(19) United States
(12) Patent Application Publication
(10) Pub. No.: US 2012/0028613 A1
(43) Pub. Date: Feb. 2, 2012

(54) MESSAGING SYSTEM

(76) Inventor: Marcus Lewis, Ross-on-Wye (GB)

(21) Appl. No.: 12/531,473

(22) PCT Filed: Mar. 17, 2008
(86) PCT No.: PCT/GB08/00953

§ 371 Date: Sep. 15, 2010

(30) Foreign Application Priority Data
Mar. 15, 2007 (GB) 0704969.5

(51) Int. Cl. H04W 4/00; H03G 3/00

(52) U.S. Cl. 455/412.1; 381/104; 455/569.1

(57) ABSTRACT

A messaging system comprises a mobile telephone apparatus (10), an outgoing message store (30), and incoming message store (32) and control means (26) operable to control the operation of the outgoing and incoming message stores.

This invention relates to a messaging system and in particular to a voice messaging system intended for use with mobile or cellular telephones and related devices such as blue tooth ear pieces.

A number of service providers of mobile telephone services provide their customers with voice messaging services whereby, when the customer is unable to take an incoming telephone call or does not wish to take such a call, an outgoing message is transmitted to the caller by the telephone network system (the service provider) and the caller is given the option of recording a message. Subsequently, the customer can access and listen to the recorded message. Although such services often operate satisfactorily, many service providers charge their customers for the provision of their service with the result that customers may opt not to collect their messages or may become dissatisfied with the service they are receiving. A frequent complaint, becoming more prevalent over the past few years, is that it is possible for a caller to leave a message during, say, working hours on day one and for the receiver not to receive notification that this message is ready for collection, for up to 24 hours or more. The potentially disastrous consequences of this delay can easily be imagined, in terms of lost business, missed appointments, etc, and statistically there must have already occurred many situations when lives have been put at risk because the sender believes a message will be received within a ‘reasonable’ period of time from being left with the service provider. Additionally, the customer may wish to be able to screen incoming calls and this is not possible once a call has been diverted to the messaging service.

According to the present invention there is provided a messaging system comprising a mobile telephone apparatus, an outgoing message store, an incoming message store, and control means operable by a user to control the operation of the outgoing and incoming message stores.

The component parts of the messaging system may be housed within a common housing and so form a single unit. Alternatively, some of the component parts may be housed in separate housings and may communicate with one another by wireless transmission or through suitable electrical connections. For example, some of the component parts may be mounted upon or within an earpiece type housing. The earpiece type housing may be designed for use with other equipment, for example audio enabled sunglasses. Alternatively, the earpiece type housing may comprise a hands-free type device arranged to communicate with the mobile telephone apparatus via a wireless, for example blue tooth, communications link.

The control means is preferably operable to permit the input sound signal from a microphone to be muted to allow screening of calls. Preferably, the user can control the apparatus to determine whether or not the input sound signal is muted, thereby permitting mobile telephone conversations to be conducted in the normal manner, if desired.

The invention is advantageous in that as the messages are stored locally, there is no necessity to dial into or otherwise access a remote storage system. The inconvenience and cost associated therewith can thus be avoided. Further, if the message can be left on the system according to the invention, then it can be retrieved by the receiver, under most ‘reasonable’ conditions and in a ‘reasonable’ time, which is sometimes not the case with messages stored with a service provider.

The invention will further be described, by way of example only, with reference to the accompanying drawings in which:

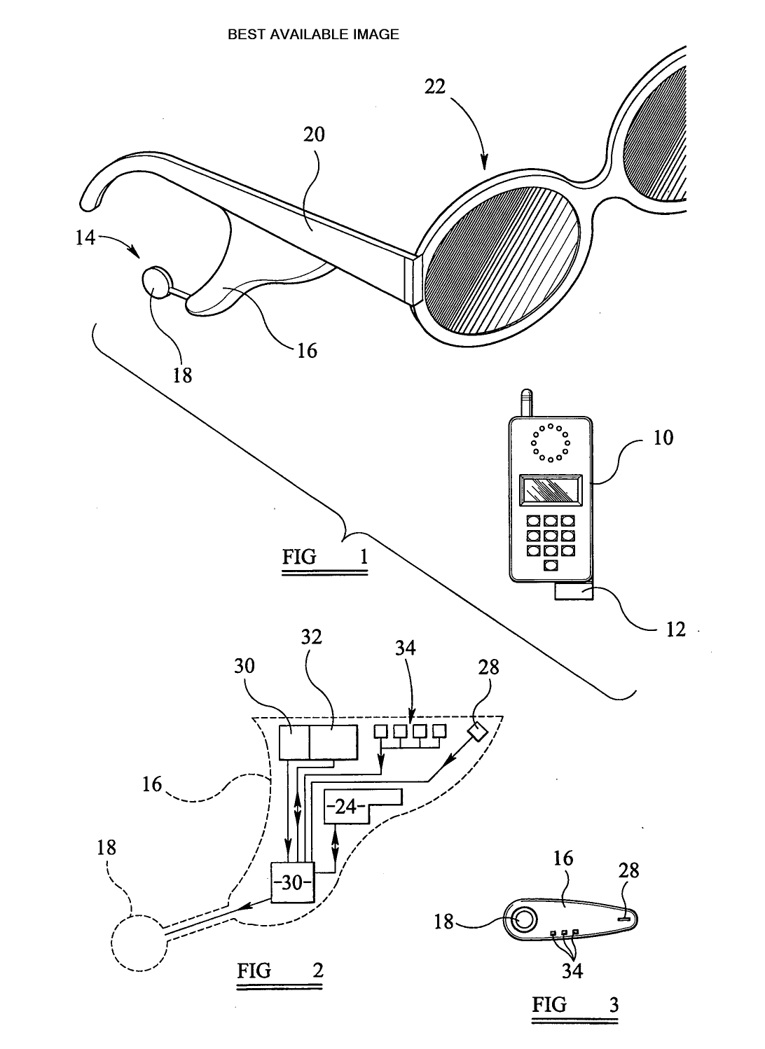

FIG. 1 is a diagrammatic representation of a messaging system in accordance with an embodiment of the invention;

FIG. 2 is a block diagram illustrating part of the system of FIG. 1; and

FIG. 3 illustrates an alternative embodiment.

The messaging system illustrated in FIGS. 1 and 2 of the accompanying drawings comprises a substantially conventional mobile telephone handset 10 which is capable of making and receiving mobile telephone calls using the services of a mobile telephone service provider and a mobile telephone communications network in the usual manner. Connected to the handset 10 is a transmitter/receiver device 12 which allows the handset 10 to communicate with other devices through a wireless communication system. Although a separate device 12 is illustrated in FIG. 1, this component could be incorporated into the mobile telephone handset 10 or may form part of the usual functionality of the handset 10. For example, it could take the form of a blue tooth type communications device, but a number of other devices are also envisaged.

The messaging system further comprises an earpiece 14 in the form of a housing 16 carrying a speaker 18 adapted to be located adjacent or in a user's ear. The housing 16 is adapted to be mounted upon a temple 20 of a pair of spectacles or sunglasses 22.

The housing 16 contains a transmitter/receiver device 24 adapted to communicate with the device 12 mounted upon or associated with the handset 10. The device 24 is connected to a control unit 26 which, in turn, is connected to the speaker 18. The control unit 26 is further connected to a microphone 28.

In one mode of operation of the messaging system, the system allows the user to make and receive mobile telephone calls in a hands-free manner. In this mode of operation, voice or sound signals from the microphone 28 pass through the control unit 26 transmitter/receiver device 24 and transmitter/receiver device 12 to the mobile telephone handset 10 from which they are transmitted to the mobile telephone communication network in the usual manner. Signals received from the mobile telephone communications network by the handset 10 are transmitted by the device 12 and received by the device 24 from which they are passed through the controller 26 to the speaker 18.

In addition to allowing the user to make and receive mobile telephone calls in a hands-free manner, the messaging system also provides a local messaging service. In order to do this, the messaging system further comprises an outgoing message store 30 and an incoming message store 32, both of which are connected to the control unit 26. Actuators 34 are further provided and connected to the control unit 26 to allow the user to control operation of the messaging system.

In use, upon receiving an incoming mobile telephone call, the user may if he wishes press an appropriate one of the actuators 34 to instruct the control unit 26 to answer the incoming call by playing the outgoing message stored in the outgoing message store 30 so that this message is transmitted to the caller. During this mode of operation, the microphone 28 is muted so that only the outgoing message from the outgoing message store 30 is heard by the caller. The outgoing message will give the caller the opportunity to leave a message, and so at the end of the transmission of the outgoing message from the outgoing message store 30, the control unit 26 will control the messaging system so as to store incoming voice signals from the caller in the incoming message store 32. During this phase in the operation of the messaging system, the microphone 28 continues to be muted. However, if desired the received signal may still be transmitted by the speaker 18 so as to give the user the opportunity to override the messaging system and take the incoming call after hearing the identity of the caller or the subject-matter about which the caller is calling. In the event that the caller wishes to accept a call answered in this manner, an appropriate one of the actuators 34 is depressed so as to instruct the control unit 26 to terminate storage of the incoming call data in the incoming message store 32 and to switch on the microphone 28 so as to allow the transmission to the caller of voice signals from the user. The telephone call can then continue in the usual manner. Alternatively, if the user does not wish to take the call, another of the actuators 34 may be depressed so as to mute the speaker 18, the microphone 28 continuing to be mute, whilst allowing the caller to continue to record his message in the incoming message store 32.

At a subsequent time when the user wishes to retrieve his messages, actuation of an appropriate one of the actuators 34 instructs the control unit 26 to replay the stored messages from the incoming data store 32 to the earpiece 18. Subsequent actuation of a suitable one of the actuators 34 may be used to delete one or more of the recorded messages.

The outgoing message stored in the outgoing message store may be a pre-recorded standard message, or alternatively may be recorded by the user.

Message data stored in the incoming data store is conveniently stored in packets of a fixed length, for example in 4 second long packets, thereby allowing the memory capacity of the incoming data store to be used in an efficient manner.

If desired, the messaging system may be incorporated into or adapted for use with an audio-enabled pair of sunglasses which are also capable of playing, for example, MP3 files or other recorded music or data files to the user.

As well as allowing the storage of incoming mobile telephone calls, the messaging system may also be capable of being operated to allow the user to record memorandums or voice messages for himself.

Although described and illustrated as being suitable for use with a pair of spectacles or sunglasses 22, it will be appreciated that the messaging system may take a wide range of forms and could, if required, all be incorporated into a mobile telephone handset or other device. FIG. 3 illustrates, diagrammatically, one alternative form in which, rather than intended for use with audio enabled spectacles, the device forms a hands-free device for use with a mobile telephone. The functionality of the device is as described hereinbefore. In such a device, the actuators 34 which enable the user to navigate the various functions outlined above can all be contained in a single joggle wheel device, or other control device, to save space. As the earpiece is of fairly small dimensions in order to be of a compact design, minimising the number of actuators is advantageous. Alternatively, the device may be fully or partly voice activated to achieve a complete hands free operation for use when driving, etc. Further, in the case of a blue tooth ear piece, when the device is returned to a charger docking station, the stored messages may be automatically downloaded to a larger memory storage device in the docking station. This storage device may have a sufficient large capacity to store many hours of such messages, which may be automatically catalogued for ease of reference and retrieval, through a simple LCD window on the docking station.

The messaging system in accordance with the invention is advantageous in that voice messages are stored locally rather than remotely and so can be accessed without having to dial into a system operated by the mobile telephone communications network. As a result, the messages can be replayed conveniently, substantially instantaneously and without cost to the user. Further, the system may be operated to allow the user to screen incoming calls and to only answer those from specific individuals or relating to specific subjects, if required.

It will be appreciated that a range of modifications and alterations to the arrangement described hereinbefore are possible without departing from the scope of the invention.

1. A messaging system comprising a mobile telephone apparatus, a local outgoing message store, a local incoming message store, and control means operable by a user to control the operation of the outgoing and incoming message stores.

2. A system according to claim 1, wherein the control means communicates with the mobile telephone apparatus using a wireless transmission system.

3. A system according to claim 1, further comprising a microphone whereby sound signals can be input, the control means including means for muting the sound signal input from the microphone.

4. A system according to claim 3, further comprising user operable means operable to determine whether or not the sound signal means is muted by the control means.

5. A system according to claim 1, wherein the control means is incorporated into an earpiece.

6. A system according to claim 5, wherein the earpiece includes a speaker and the control unit is operable to control whether or not sound signals are emitted by the speaker.

7. A system according to claim 6, further comprising user operable means operable to determine whether or not the control unit permits the emission of sound signal means from the speaker.

8. A system according to claim 5, wherein the earpiece comprises a hands-free device to allow hands-free operation of at least some of the functions of the mobile telephone apparatus.

9. A system according to claim 5, wherein the earpiece is attachable to a temple of a pair of spectacles and/or sunglasses.

10. The combination of an outgoing message store, an incoming message store and control means for use with a mobile telephone apparatus to form a messaging system as claimed in claim 1.
